(19) United States
(12) Patent Application Publication
(10) Pub. No.: US 2015/0013738 A1
(43) Pub. Date: Jan. 15, 2015

(54) THERMOELECTRIC ENERGY CONVERSION USING PERIODIC THERMAL CYCLES

(71) Applicant: Pyro-E, LLC, San Jose, CA (US)

(72) Inventor: Shihyu Lu, Mount Laurel, NJ (US)

(21) Appl. No.: 14/326,862

(22) Filed: Jul. 9, 2014

Related U.S. Application Data
(60) Provisional application No. 61/844,001, filed on Jul. 9, 2013.

(51) Int. Cl. H01L 35/30

(52) U.S. Cl. CPC H01L 35/30
USPC 136/201; 136/205

(57) ABSTRACT

The invention provides systems, apparatuses, and methods for applying periodic thermal management for converting heat into electricity using thermoelectric devices. One method comprises the use of a fluid that performs periodic heating and cooling cycles of thermoelectric devices during fluid evaporation and condensation. The systems, devices, and methods take advantage of the Seebeck effect as a material response between heat and electricity. One apparatus uses alternating pressures to drive fluid evaporation and condensation, thereby producing periodic heating and cooling of the thermoelectric modules. Ultimately, the thermoelectric generator apparatus and method provide improvements in conversion efficiency and reductions in parasitic loss over current solid-state systems.

The present application claims priority to U.S. Provisional Patent Application Ser. No. 61/844,001, filed Jul. 9, 2013, the disclosure of which is herein incorporated by reference in its entirety.

### FIELD

Provided herein are systems and methods for the conversion of a thermal energy into electrical energy. Also provided herein are systems and methods for conversion of a temperature difference across a thermoelectric module into electrical energy. The present invention specifically pertains to the periodic heating and cooling of thermoelectric modules to maximize the conversion efficiency from heat to electrical energy. A broad base of end-users can benefit from a viable technology that converts heat energy into electricity, including applications for vehicles, generators, and other energy systems and platforms. Furthermore, the technology can provide benefit to society in the form of cheaper energy, less reliance on fossil fuel, and improved environmental quality.

### BACKGROUND

Thermoelectric effects include the direct conversion of temperature differences to electric potential differences (Seebeck effect) and electric potential differences to temperature differences (Peltier effect). The names are derived from the independent discoveries of French physicist Jean Charles Athanase Peltier and Estonian-German physicist Thomas Johann Seebeck. In 1821, Seebeck found that if two dissimilar metals are connected and there is a temperature difference across the surface junction, a voltage would develop across the junction. The Seebeck effect forms the basis of the power generation function of a thermoelectric device. In 1834, Peltier discovered the inverse Seebeck effect where if a current is flowing through two dissimilar metals connected at a junction, a temperature gradient will develop across the junction, which leads to a heat flux. The Peltier effect forms the basis of the cooling function of a thermoelectric device. In the 1900's, researchers found efficient thermoelectric materials that possess large Seebeck coefficients (S), high electrical conductivity (σ) and low thermal conductivity (κ). The performance (i.e., efficiency of Seebeck or Peltier effect) of thermoelectric materials can be expressed in terms of a dimensionless figure of merit (ZT), where Z is given by Z=S²σ/κ, and T is temperature. Now, a thermoelectric device utilizing properly doped semiconductor materials can provide high performance either in Seebeck power generation or Peltier cooling. The device usually includes dozens of p and n type semiconductor legs connected electrically in series and thermally in parallel, sandwiched between two plates made of a material that is an electrical insulator with high thermal conductivity. It normally has two power wires, the “+” and “−” connectors. When applying a voltage on the wires, it works in Peltier cooling mode, which pumps heat from one side to the other. When connecting the two power wires to an energy storage device and applying a temperature difference across the two sides, it works in Seebeck power generation mode, which generates electricity.

It is becoming more important to reduce the amount of energy generated by consumable heat source power plants, (e.g., natural gas, coal, fossil fuel, nuclear, etc.) and replace them with renewable and/or clean energy sources.

A challenge faced by current renewable clean energy technologies is that they are almost as, and in some cases, more complicated than the legacy technologies they are attempting to replace. Most of these technologies are focused on alternative generation of electricity and they miss the fact that most of the inefficiencies in getting the energy to the customer occur along the countless steps between the conversion of fuel into electrical and mechanical energy.

Factoring in the energy consumed developing, deploying and maintaining both the new and old technologies there is no return in our investment in any of them. There is a need for improved systems, devices, and/or method directed to localized, sustainable, and/or renewable clean energy that can be stored more efficiently and then converted into electrical energy when desired. The present disclosure is directed to overcome and/or ameliorate at least one of the disadvantages of the prior art as will become apparent from the discussion herein. Prior systems include:

Hayakawa (PCT Pat. No. JP2011/070181) discloses thermoelectric materials that can achieve higher Seeback effect than conventional materials. The invention discloses the use of magnetic films stacked together with thermoelectric elements. However, module-level design and optimization outline therein does not mention system level packaging to provide a means of increasing heat to electrical energy conversion efficiency.
Wang (U.S. patent Ser. No. 13/279,475) disclose a dynamic switching thermoelectric thermal management system for power generation. The modules are thermally coupled to a heat source and a heat dissipation source. A controller periodically samples the module temperature to dynamically switch the device mode from power generation to cooling, and vice versa. A battery is connected to the thermoelectric module to store the energy recovered from the heat source. No system level packaging designs were disclosed to improve the overall device efficiency.

There thus remains a considerable need for new system level packaging for thermoelectric power generation. A desirable system would reduce complexity, increase energy conversion efficiency, and help reduce the use of heavy peripheral components that requires power input. The present invention satisfies these needs and provides related advantages as well.

### SUMMARY

For most heat generating systems, a large fraction of energy is dissipated as waste heat. Most of these heat sources need passive or powered heat dissipation devices to extract the waste heat and maintain the critical components of the system within a desired temperature range. This extracted waste heat can be harvested to provide a source of electrical energy to power peripheral devices to improve the overall thermal system efficiency. Here, the temperature difference between the hot heat sources and the cold ambient makes thermoelectric power generation possible. The temperature difference creates an electric potential difference in thermoelectric materials. When an external load is connected, the thermoelectric material serves as a power source in the completed circuit.

It would be desirable to have a thermal management system that can recover thermal energy and transfer heat in a periodic manner to a substantial number of thermoelectric modules. Without module level modifications, one or more embodiments disclosed herein increases energy conversion efficiencies above that of single modules. In summary, exemplary features of the periodic heat transfer apparatus and method for thermoelectric energy conversion include:
Permitting high heat transfer rates of boiling and condensation to achieve uniform, accurate and fast period heating of thermoelectric modules.
Permitting higher system-level than module-level efficiency in thermal to electrical energy conversion.
Permitting zero-g or high-g operation by using liquid wick for fluid distribution.

Thus several advantages of one or more aspects are to provide accurate, uniform and fast periodic heat cycles to a substantial number of thermoelectric modules. These and other advantages of one or more aspects will become apparent from a consideration of the ensuing description and accompanying drawings.

In some embodiments, provided herein are periodic heat transfer methods for performing an energy conversion procedure comprising: a) providing one or more thermoelectric modules with a first and a second surface; b) providing a first fluid in contact with the first surface; c) providing a second fluid in contact with the second surface; and d) changing the temperature of the first surface and the second surface during a phase change of the first and second fluids in a manner predetermined by an energy conversion procedure. In some embodiments, one or more or all components shown in FIGS. 1, 2, and/or 4 are employed in the method.

In some embodiments, systems and devices are provided for carrying out the method above. In some embodiments, the system comprises one or more of a computer processor, computer readable media, and software for managing the operation of the system/device (e.g., controlling the timing of the temperature change, displaying information to a user (e.g., a monitor or other display), permitting programming of system parameters by a user, collecting or storing data associated with use of the system/device or performance parameters of the system/device, etc.).

### BRIEF DESCRIPTION OF THE DRAWINGS

The accompanying drawings illustrate one or more embodiments of the disclosed method and apparatus used in generating electricity from heat. The embodiments will now be described with reference to the accompanying drawings, in which:

FIG. 1 is a schematic depicting the sectional view in accordance with an embodiment of the invention.

FIGS. 2A, 2B, 2C are schematics depicting the sectional and perspective views for the wick structure component in accordance with an embodiment of the invention.

FIGS. 3A and 3B are plots depicting the temperature and efficiency for a thermoelectric generator in accordance with an embodiment of the invention.

FIG. 4 is a plot showing the sectional view in accordance with an embodiment of the invention.

### DETAILED DESCRIPTION

Henceforth, the terminology ‘fluid’ is used interchangeably with saturated or superheated vapor, saturated or undercooled/supercooled liquid, or a mixture of vapor and liquid. The fluid may comprise a first and a second fluid component of different molecular composition. The first and second fluid components may exist in the same or different phases, e.g. solid, liquid or gas/vapor. In the liquid phase, the first and second fluid components may be miscible or immiscible. When in gas phase, the first and second component will mix uniformly through intermolecular diffusion. The first and second fluid components may also exist as a two-phase mixture at different ‘quality’ ratios, as measured by the mass or mole fraction of the first fluid component of the whole mixture. Multi-component fluids may comprise 3 or more molecular species. A working fluid may refer to a fluid body inside a closed loop that receives heat from a source and rejects that heat to the surrounding environment.

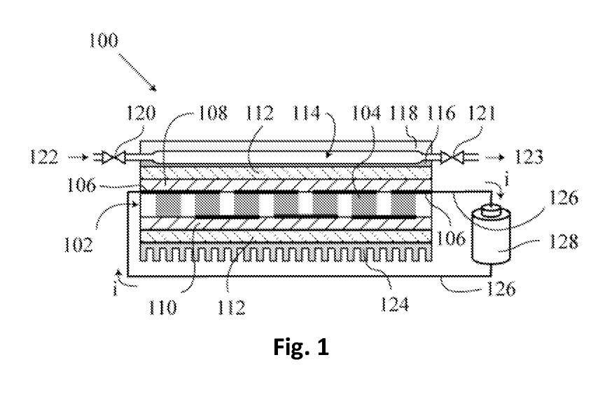

The thermoelectric module is familiar to those skilled in the art as a solid-state technology that operates on the Seeback effect to generate an electric potential from a temperature gradient kept across a plurality of interconnected semiconductor pellets 104 (FIG. 1). The interconnected pellets 104 are thermally in parallel and electrically in series. In this manner, they experience identical temperature difference and yet generate additive voltages. The total amount of electrical energy generated, W, can be expressed as i²×R, where i is electric current flowing across an external resistor of resistance, R. The energy conversion efficiency, η, of module 102, is expressed as W/Q as the ratio between electrical energy and thermal energy transferred across the top and bottom surfaces of said module. Since the current generated is proportional to the temperature difference, namely i˜ΔT, the resulting efficiency of at least one type of thermoelectric module would follow η˜ΔT².

### FIG. 1

Referring to FIG. 1, the schematic of at least one embodiment of a thermoelectric (TE) device or system 100 that may be used to convert thermal energy into electrical energy. The thermoelectric device 100 includes a plurality of thermoelectric module 102 that comprises components 104, 106, 108, 110. Specifically, module 102 holds a plurality of semiconductor legs or pellets 104 that exhibit the thermoelectric effect. Interconnecting the semiconductor pellets 104 are electrically conducting linkages 106 that interconnects adjacent said pellets. The thermoelectric module 102 also comprises a first and a second surface in direct thermal contact with electrically insulating plates or substrates 108, 110. On the first substrate 108, a thermal interface material 112 forms thermal contact between said substrate and at least one pressure vessel or chamber 114. In at least one embodiment, chamber 114 comprises first and second chamber components. First component comprises a thermally conductive, rigid base plate 116 that is place in thermal contact with substrate 108 using thermal interface material 112. Second component comprises thermally insulated, rigid cover plate 118 that in various embodiments is exposed to the surrounding external environment. First and second components 116, 118 are mated in a manner that prevents fluid leakage at substantial pressures. In at least one embodiment, chamber 114 is also connected directly or indirectly to a first valve 120 and a second valve 121. Valve 120 leads to an entrant heat transfer or working fluid 122 and valve 121 leads to an exit heat transfer or working fluid 123. On the second substrate 110, thermal interface material 112 is used to form a thermally conductive interface between said substrate and a thermal heat sink 124. Electrical wires or leads 126 connects the linkages 106 to an external resistive load 128 that in various embodiments either stores or uses up the electricity, i, that flows out of the thermoelectric module 102.

In more detail, chamber 114 provides a means of substantial speeds of heat transfer with module 102 for at least one embodiment. Chamber 114 also provides a means of thermal retention to reduce heat transfer to and from the surrounding environment. Chamber 114 in various embodiments provides the means of receiving, maintaining and rejecting a predetermined amount of fluid 122 at substantially high positive and negative, or vacuum, pressures. In various aspects, chamber 114 provides a means of allowing the entrant fluid 122 to uniformly and quickly condenses inside said chamber. In various aspects, chamber 114 provides a means of allowing the inside fluid to uniformly and quickly evaporate as exit fluid 123.

In more detail, heat sink 124 provides a means of substantial heat exchange, e.g., heating and cooling, with module 102. In various aspects, heat sink 124 provides a means of low thermal resistance with the surrounding. As understood by those skilled in the art, thermal resistance is measured by the temperature difference needed between two bodies for a given unit of heat transfer. Typical thermal resistances values are given in ° C. m²/W. Minimizing thermal resistance therefore improves the rate of heat exchange between any two bodies. Also, the thermal interface material 112 provides the means of reducing the thermal resistance at the interface between 108, 116 and 110, 124. The valve 120 provides a means of controlling, pulsating and modulating the flow of a heat transfer fluid 122 into and out of chamber 114. In various aspects valve 120 also provides a means of controlling the fluid flow rate with substantial accuracy entering and leaving chamber 114.

In specific detail, the typical thermal resistance of the thermal interface material 112 should be <1.0° C. m²/W. For base plate 116, the thermal resistance can range 0.1-10° C./W. The cover plate 114 should have 100-200° C. m²/W. Heat sink 124 should have 0.1-10° C. m²/W.

In further detail, fluids 122, 123 are a single or a multi-component substance with predetermined thermodynamic states that correspond to either the vapor, liquid or the solid phase. These states are fully definable by temperature, pressure and density. At transition between the phases, or phase saturation, only temperature and pressure together defines the state of fluid 122. In one or more embodiments, fluid 122 have properties that are at or near the aforementioned saturation states. Given these conditions, the temperature and pressure of fluid 122 would not vary independently. As a result, maintaining fluid 122 at or near saturation inside chamber 114 provides a means of controlling the temperature of said fluids by changing the pressure of said fluid. As a result, the pressure-drive temperature change of fluid 122 provides a means of exchanging thermal energy in substantial heat transfer rates with the thermoelectric module 102. For various embodiments during operation, fluid 122 inside chamber 114 may be in the range of 0.1-200 psi and −50-400 C.

In further detail, still referring of FIG. 1, the hardware specifications described below should satisfy the design of one or more embodiments. Module 102 is sufficiently wide (W), long (L) and tall (H) to provide sufficient thermal efficiency, reliability, and conformation to system constraints. Module 102 may have outer dimensions 2″ by 2″ by 0.2″ (W×L×H) to hold a substantial mass quantity of semiconductor pellets 104. The thickness of the thermal interface material 112 may be between 1-100 micrometers, depending on the compressive force applied between adjacent components. Next, chamber 114 may have out dimensions 2″ by 2″ by 1″ (W×L×H) and inner dimensions 1.5″ by 1.5″ by 0.25″ (W×L×H). Base plate 116 may have outer dimensions 2″ by 2″ by 0.1″ (W×L×H) and cover plate 118 2″ by 2″ by 2″ by 0.65″ (W×L×H). Heat sink 124 may have outer dimensions 2″ by 2″ by 1″ (W×L×H) and characteristic feature dimension of 1/16″. The said features may include square or circular posts that extends from the base of heat sink 124. Electrical wire 126 may be 10-25 gauge copper material that connects to the resistive load 128. The aforementioned components should all have lengths and widths that match the overall area for a predetermined plurality of module 102. For example, using two modules 102 would require approximately doubling the area of components 114 and 124. Alternative dimensions may be used as desired for a particular use or application.

In further detail, all components should be constructed using materials that can withstand substantial compressive forces. Compression with pressures in the range of 100-300 psi may be used to provide a means of reducing the thickness of thermal interface 112. Substantial compression would therefore reduce the thermal resistance between adjacent components 108, 110, 114, 124 as shown FIG. 1. In various embodiments, components 108, 110, 114, 124 use materials with low coefficient of thermal expansion (CTE). This reduces material expansion differences during heat transfer and therefore the interfacial stresses caused by the temperature gradients across adjacent components 108, 110, 114, 124. The material chosen should have CTE values <10⁻⁵° C.⁻¹. Also, components 116, 124 should have substantially high thermal conductivities with values >100 W/m-K (e.g. aluminum, aluminum nitride, stainless steel, etc). Cover plate 118, in contrast, should have designs that provide a means to reduce thermal conductivity to values <10 W/m-K (e.g., zirconia, silicon nitride, etc.). Plate 118 may be constructed with inner and outer walls. Vacuum may be formed inside said walls as a means for better heat retention or thermal insulation. Components 116, 118 should also have sufficient heat resistance to temperatures up to 300-450 C as a mean to provide reliable operational life for at least one embodiment.

In further detail, valves 120, 121 can be a pneumatic, a solenoid, or any other electromechanical valve types. Valves 120, 121 may be 2-way, 3-way, or other multi-way valve types. Valves 120, 121 can be attached to chamber 114 either with threaded, welded or other hermetic connections, as a means to prevent fluid leakage under positive or negative gauge pressures up to ˜250 psi gauge pressure. Valves 120, 121 should also be able to quickly open and close with substantially precise timing as to allow a predetermined amount of vapor to pass through (e.g. 1-10 Hz with 10% accuracy). The duration of the opening for valves 120, 121 is typically 0.001-1 second to allow precise heating and cooling control. Furthermore, the seals of valves 120, 121 should use a material able to withstand substantially high (e.g., stable up to 350° C. such as fluoroelastomer, silicone, PTFE or other compounds). The valve seals should also be chemically compatible, e.g. no degradation over time, to the chosen fluid 122, 123. In various aspects, valves 120, 121 may be actively and remotely controlled in ways understood by those skilled in the art, as means of simplifying at least one embodiment with a lesser substantial number of external inputs.

In further detail, the schematic of FIG. 1 describes at least one embodiment of the disclosed method and apparatus used in generating electricity from heat. The manner for which at least one embodiment operates is described as follows. The process involves first and second processes of opening valves 120, 121 that are repeated in a predetermined number of cycles. Initially, heat sink 124 is placed in open air or in a closed liquid cooling loop. Closed liquid loop, as understood by those skilled in the art, is used to provide a means of rejecting heat into the surrounding ambient. Also, chamber 114 is at substantially low pressure at this point of time and fluid 122 is at a substantially high pressure. Subsequently, valve 120 opens and fluid 122 enters chamber 114. As fluid 122 fills chamber 114, the said fluid condenses onto the surfaces of the cold wall and transfers its latent heat to the base plate 116. Pressure will now rise inside chamber 114 at a rate that is fast initially but falls with time. As a result, the latent heat of fluid 122 is transferred in substantial volume or mass fraction to module 102. This first process of opening valve 120 provides a means of heating top plate 108. After a predetermined amount of time have elapsed, valve 120 closes and is kept closed. Subsequently again, after a predetermined amount of elapsed time, fluid inside chamber 114 has reached a substantially low pressure. Then, valve 121 opens and fluid inside chamber 114 is ejected out as low-pressure fluid 123. This second process of opening valve 121 provides a means of cooling top plate 108. Subsequently, after a predetermined time had elapsed, the first and second processes are repeated for a predetermined number of cycles as a means to generate electricity from heat.

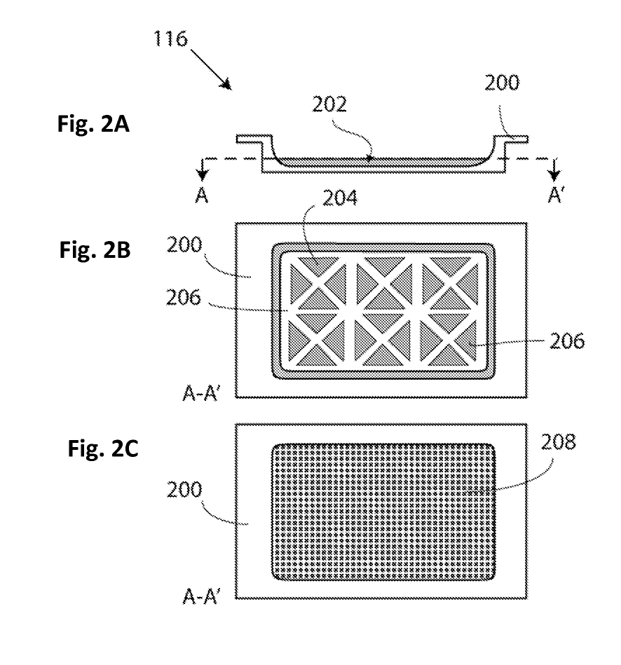

### FIGS. 2A, 2B, 2C

Referring to FIGS. 2A, 2B, 2C, the schematics depict at least one embodiment of the components in part of the disclosed method and apparatus used in generating electricity from heat. The schematic of at least one embodiment of the bottom cover plate component 116 of the working fluid chamber 114. Specifically, cover plate 116 comprises a thermally conductive base or substrate 200. Substrate 200 comprises first and second surfaces. In reference to FIG. 1, the first surface is put in direct thermal contact with other components of the device. The second surface of substrate 200 contains a porous structure such as foam or wick 202.

In further detail, with reference to FIG. 2A, at least one embodiment has a substrate 200 constructed in a manner that provides fast heat transfer from the first side to the second side of said substrate. Substrate 200 as a component of chamber 104 provides a means of sealing against fluid leak to maintain pressure or vacuum of said fluid inside said chamber. Also substrate 200 contains a means of mounting wick 202 securely and in good thermal contact. In at least one embodiment, wick 202 provides a means of retaining fluids in their liquid phase. The open structure of wick 202 provides extended surface area for a means of distributing liquid evenly, countering the effect of gravity, and those related to inertial force. The advantage of which improves the heat transfer characteristics of the fluids inside chamber 114. Also, the extended surface area of wick 202 provides a means of promoting nucleation sites for the condensation or evaporation processes during heating and cooling, respectively. The advantage is to improve the temperature uniformity within the confining vessels. Also, the liquid-retaining property of wick 202 provides the means of preventing dry-out and hot spots. These conditions occur during evaporation when a particular surface area becomes dry and can no longer promote the latent heat transfer effect during phase change.

In further detail, with reference to FIG. 2B, at least one embodiment has a bimodal structure foam or wick 204 contained within substrate 200. The screen 204 provides a means of distributing and retaining liquid inside the pore structure of said screen. The extended surface area of screen 204 also provides nucleation sites for fluid condensation and evaporation. In comparison, wick 204 is arranged in a manner that provides open vapor space 206 in between said wick. In comparison, wick 204 provides the same advantages to the various embodiments as described for wick 202. The differences between wick 202 and 204, and the associated advantages, are described as follows. During evaporation, fluid vapor escapes out of for the bimodal wick 204 and into space 206. Space 206 has substantial spacing for providing a means of fluid exchange and vapor transport. The resultant advantage is to increase the rate of evaporation and therefore the rate of heat transfer from the first side to the second side of substrate 200 and vice versa.

In further detail, with reference to FIG. 2C, at least one embodiment has a substrate 200 that contains a wired screen 208. The screen 208 provides a means of distributing and retaining liquid inside the pore structure of said screen. The extended surface area of screen 208 also provides nucleation sites for fluid condensation and evaporation. The advantages provided by wired screen 208 is the reduced cost associated with the manufacturing process.

In further detail, with reference to FIGS. 2A, 2B, 2C, the average pore size of the open structure wick 202, 204, 208 is in general less than <100 micrometers. The overall thickness of wick 202, 204 is substantial to avoid dry-out, which is typically between 0.1 and 5 millimeters thick. The said wick material may be ceramic, plastic, metallic, or a composite of all three. The wick material may be inherently hydrophilic or it may comprise a surface treatment, e.g. hydrophilic coating, to maximize liquid transport. In addition, material of wick 208 may comprise oxidized copper or aluminum screen, mesh or cloth that has mesh sizes larger than 100×100 or opening widths less than 200 micrometers. The thickness of wick 208 may comprise or consist of 1-10 layers of the screen wick, with each layer having the thickness of 5-500 micrometers.

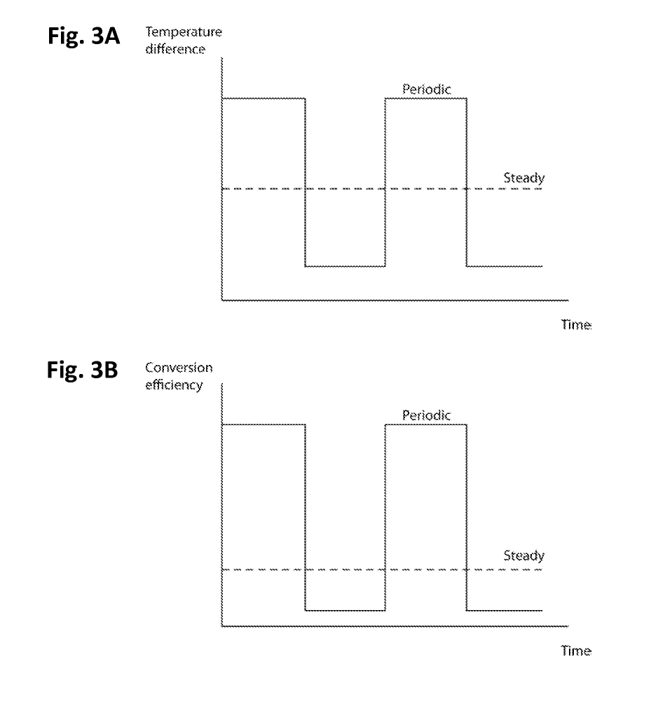

### FIGS. 3A and 3B

Referring to FIGS. 3A and 3B, the schematics illustrate the experimental data acquired from at least one embodiment of the disclosed method and apparatus used in generating electricity from heat. Referring to FIG. 3A, the data describes the temperature difference, ΔT, between the first component 108 and second component 110 of module 102. In at least one embodiment, the temperature difference is periodic. The periodicity may be described by its duty cycle in a manner understood by those skilled in the art. This would correspond to the disclosed method and apparatus for transferring heat periodically to the module 102. Alternatively, a steady heat transfer to the module 102 would result in a constant, steady temperature difference. Both periodic and steady temperature difference profiles are shown in FIG. 3A.

Referring to FIG. 3B, the data describes the energy conversion efficiency, η˜ΔT², of module 102 when exposed to a periodic and a steady heat. In at least one embodiment, the manner in which ΔT changes as a function of time is described in reference to FIG. 3A. In the periodic case, the conversion efficiency has the same duty cycle with increasing time. Alternatively, in the steady case, the conversion efficiency follows a constant value with increasing time. By comparison, the difference between periodic ΔT and steady ΔT is that the time-averaged η is higher for the periodic ΔT case than the steady case. These and other advantages associated with energy conversion efficiency using periodic temperature control of at least one embodiment should be understood by those skilled in the art.

In reference to FIGS. 3A and 3B, the typical values of the parameters are disclosed as follows. The temperature difference, ΔT, may be maintained between 50-500° C. Efficiency, η, as a measured ratio between electrical energy output to the thermal energy input, is typically expected to be in the range of 5-10% for steady ΔT. For the periodic case, η may be expected in the range of 10-20%.

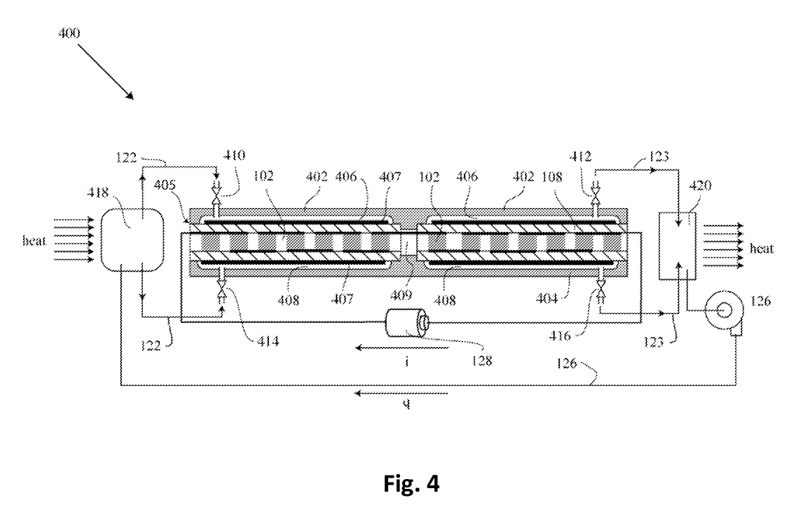

### FIG. 4

FIG. 4 illustrates a sectional view of at least one additional embodiment of the disclosed method and apparatus used in generating electricity from heat. The energy conversion system 400 uses a plurality of thermoelectric modules 102. Each of the modules 102 has a first and a second side. At least one embodiment comprises first and second cover plates 402, 404. The first plate 402 forms physical contact against the first side of modules 102. The second plate 404 forms physical contact against the second side of modules 102. A sealing paste, bonding agent or rubber gasket 405 is applied between the aforementioned contacts between modules 102 and 402, 404. Between the plurality of modules 102 and first plate 402, there is a first fluid cavity or chamber 406. Between the plurality of modules 102 and second plate 404, there is a second fluid cavity or chamber 408. Inside fluid chambers 206, 208, a screen mesh or porous wick 407 is put into direct thermal contact with the first and second sides of modules 102. In between the plurality of modules 102, a vacuum space 409 is provided in the space between said modules. The first chamber 406 has at least one hot valve 410 and a cold valve 412. The second chamber 408 has a hot valve 414 and a cold valve 416. The hot valves 410, 414 are both connected to an evaporator 418, which receives heat from a thermal source. The cold valves 412, 416 are both connected to a condenser 420, which reject heat to the ambient environment. A liquid pump 422 returns the fluid 126 to evaporator 418 to complete a closed fluid loop.

In further detail, FIG. 4 illustrates the use of a plurality of thermoelectric modules 102 for a means of increasing the energy output of the device 400. In various embodiments, modules 102 are placed in parallel to the flow of heat as a means of having similar temperature difference across the first and second surfaces of said modules. The modules 102 may also be arranged in series to the flow of heat as a means of creating a cascade of temperatures across the first and second surfaces of said modules. In various aspects, modules 102 are interconnected in series or parallel to the flow of electricity to modulate the voltage output as a means of reducing electrical loss and/or other associated advantages of optimizing the device operation.

The first and second cover plates 402, 404 confines the first and second surfaces of modules 102 as a means of providing structural support and rigidity for the said modules. The plates 402, 404 are constructed in a manner that provides a means of thermal retention to reduce heat transfer to and from the surrounding environment. Plate 402, 404 also provide internal cavities so that when placed against modules 102, fluid chambers 406, 408 are created at the first and second surfaces of modules 102. The fluid chamber 406 may be either connected into one large cavity or divided into separate cavities. Similarly, the fluid cavity 408 may be either connected into one large cavity or divided into separate cavities. The said arrangements of chamber 406, 408 provide a means of controlling fluid flow and the temperature of either the first or the second side of modules 102. In further detail, chambers 406, 408 in various embodiments provide the means of receiving, maintaining and rejecting a predetermined amount of fluids 122, 123 at substantial positive and negative, e.g. vacuum, pressures. In various aspects, chambers 406, 408 provide a means of allowing the entrant fluid 122 to uniformly and quickly condense inside said chamber. Chambers 406, 408 provide a means of allowing any internal fluid to uniformly and quickly evaporate as exit fluid 123.

In reference to FIG. 4, at least one embodiment has a plurality of hot and cold valves 410, 412, 414, 416 that are connected to the cover plates 402, 404. The said valves provide a means of throttling, pulsating and modulating the flow of the entrant fluid 122 and the exit fluid 123 in and out of chambers 406, 408. Valves 410, 412, 414, 416 operate in a manner such that a substantially precise amount of fluids 122, 123 enters and exits chambers 406, 408.

In further detail, evaporator 418 may also be referred to a heat exchanger that receives heat or thermal energy from the surrounding. Evaporator 418 holds the entrant fluid 122 at substantially high pressures and temperatures as predetermined by the disclosed method and apparatus. Evaporator 418 is provided with substantial surface area and internal volume as a means to maintain the predetermined operating temperature and pressure inside said evaporator. Similarly, in various embodiments, condenser 420 holds the exit fluid 123 at substantially low pressure and temperatures as predetermined by the device operation disclosed herein. Condenser 420 is provided with substantial surface area and internal volume as a means to maintain the predetermined operating temperature and pressure inside said condenser. For both evaporator 418 and condenser 420, larger surface area provides the advantage of lesser thermal resistance against heat transfer to the ambient surrounding, as understood by those skilled in the art. Also, large inner volume of evaporator 418 and condenser 420 provides the advantage of a better thermal sink to maintain working conditions during fluid transport in and out said evaporator and said condenser.

In further detail, the schematic of FIG. 4 describes at least one embodiment of the disclosed method and apparatus used in converting heat into electrical energy. The manner for which at least one embodiment operates is described as follows. The process involves first and second processes of opening valves 410, 412, 414, 416 that are repeated in a predetermined number of cycles. In the first process, chamber 406 is at a substantially low pressure and temperature and chamber 408 is at a substantially high pressure and temperature. Entrant fluid 122 is now at a substantially high pressure and temperature and exit fluid 123 is at a substantially low pressure and temperature. Valves 410, 412, 414, 416 are now closed. Subsequently, valve 410 opens and fluid 122 enters chamber 406. As fluid 122 fills chamber 406, the said fluid condenses onto the surfaces said chamber. Pressure will now rise inside chamber 406 and the process heats the first side of modules 102 from the latent heat of fluid 122 absorbed by said module. Concurrently, valve 416 opens to allow the inner fluid to evaporate. Pressure now falls to a substantial level inside chamber 408 and this process cools the second side of module 102 as the latent heat is absorbed by the exit fluid 123.

In further detail, the second process of the manner for which at least one embodiment converts heat into electrical energy is described as follows. In the second process, chamber 406 is at a substantially high pressure and temperature and chamber 408 is at a substantially low pressure and temperature. Entrant fluid 122 is now at a substantially high pressure and temperature and exit fluid 123 is at a substantially low pressure and temperature. Valves 410, 412, 414, 416 are now closed. Subsequently, valve 414 opens and fluid 122 enters chamber 408. As fluid 122 fills chamber 408, the said fluid condenses onto the surfaces said chamber. Pressure will now rise inside chamber 408 and this process heats the second side of modules 102 from the latent heat of fluid 122 absorbed by said module. Concurrently, valve 412 opens to allow the inner fluid of chamber 408 to evaporate. Pressure now falls to a substantial level inside chamber 408 and this process cools the first side of module 102 as the latent heat is absorbed by the exit fluid 123.

In further detail, in reference to FIG. 4, for at least one embodiment that converts heat into electrical energy, the first and second processes of the manner are repeated continuously. The orientation of device 400 may be horizontal or vertical in respect to gravity. During fluid evaporation, liquid drain would be driven out by gravity and this would provide a means of improving the cooling rate of either the first or the second side of module 102. In at least one embodiments, a plurality of device 400 are interconnected in parallel or in series configurations as a means to increase electrical energy output at nearly the same thermal efficiency as single module systems. In various embodiments, electronic control hardware and algorithm may be included to control the timing of operation for a plurality of valves used.

The advantages of the embodiments include, without limitation, the use of phase-changing fluid to provide the periodic heating, cooling and the temperature differences across thermoelectric modules. From the description, a number of advantages of various embodiments of the periodic heat transfer method become evident and include, but are not limited to:
a. It permits higher thermal efficiency η for converting heat to electricity using thermoelectric modules than current methods by using fluids that undergo phase change.
b. It permits the use of smaller, less powerful pumps than prior systems and methods that use only steady-state heat transfer methods.
c. It obviates the need for a metal substrate or heat sinks typically used in prior systems to increase heat transfer to the ambient surrounding. This thus reduces the mass of the overall system given a specific power output.
d. It differentiates from other thermoelectric generator systems by which heat is transferred to the device in a periodic, time-varying manner. The heat transfer method based on fluid condensation and evaporation is also different from others that use single-phase gases and/or liquids. The advantage is that pressure can be modified quicker and more uniformly than prior methods of using forced thermal convection and thermal conduction.

In some embodiments, the disclosed systems, devices, and methods also comprise various embodiments that include add-ons or external elements that improve the overall heat to electricity conversion process. One or more of these elements include components that control the timing of the operation, including, but not limited to, thermocouples, pressure transducers, electronic circuitry coupled with control algorithm. These components may have the ability to synchronize a plurality of thermoelectric modules as a means of improving the energy conversion efficiency of the overall system.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention.

We claim:

1. A periodic heat transfer method for performing an energy conversion procedure comprising:
i. providing one or more thermoelectric modules with a first and a second surface;
ii. providing a first fluid in contact with said first surface; and
iii. providing a second fluid in contact with said second surface; and
iv. changing the temperature of the said first surface and the said second surface during a phase change of the said first and second fluids in a manner predetermined by an energy conversion procedure.

2. A device configured to carry out the method of claim 1.

3. A system comprising the device of claim 2 and a computer processor.
